(19) United States
(12) Patent Application Publication
(10) Pub. No.: US 2010/0020864 A1
(43) Pub. Date: Jan. 28, 2010

(54) PULSE TRANSMITTING DEVICE, PULSE RECEIVING DEVICE, PULSE COMMUNICATION SYSTEM, AND PULSE COMMUNICATION METHOD

(75) Inventors: Michiaki Matsuo, Osaka (JP); Hitoshi Asano, Miyagi (JP); Hideki Aoyagi, Miyagi (JP); Kazuaki Takahashi, Osaka (JP); Yew Soo Eng, Singapore (SG)

Correspondence Address: Dickinson Wright PLLC;James E. Ledbetter, Esq., International Square, 1875 Eye Street, N.W., Suite 1200, Washington, DC, 20006, US

(73) Assignee: Panasonic Corporation, Osaka (JP)

(21) Appl. No.: 12/374,994

(22) PCT Filed: Jul. 12, 2007
(86) PCT No.: PCT/JP2007/063920

§ 371 Date: Feb. 26, 2009

(30) Foreign Application Priority Data
Jul. 24, 2006 (JP) 2006 201359

(51) Int. Cl. H03K 7/04; H04L 27/06

(52) U.S. Cl. 375/239; 375/340

(57) ABSTRACT

A pulse transmitting device is provided to avoid interference between pulses due to multipath influence even in a high speed pulse transmission that is typical of a UWB by making use of a relatively simple method and to improve receiving quality. In the device, a pulse adjusting unit (110) generates pulses in response to transmitting data, a non-use interval setting unit (120) sets up a non-use interval where the pulses generated by the pulse adjusting unit (110) are not transmitted on the basis of a delay time that a delayed pulse caused by the multipath delays from a main pulse and takes until arriving at a communication partner. A pulse position adjusting unit (130) adjusts a pulse position not to transmit the pulses during the non-use pulse interval. An RF transmitting unit (140) converts the pulse, the position of which is adjusted by the pulse position adjusting unit, to a wireless frequency band and transmits a pulse wireless signal after the conversion to the communication partner.

### 1. TECHNICAL FIELD

The present invention relates to a pulse transmitting apparatus, pulse receiving apparatus, pulse communication system and pulse communication method adopting high speed pulse communication.

### 2. BACKGROUND ART

In recent years, there is need for applications for cross-connecting devices such as mobile telephone terminals, audio visual devices, and personal computers and peripheral devices and communicating data such as multimedia information between the devices, so that, for example, it may be possible to manage music data that is recorded on an audio device on a personal computer or transfer video data that is recorded on a visual device to a mobile telephone terminal and view the video data outdoors. As a means for meeting this demand, one possibility is to connect devices with cables and build a network. However, building a cable network involves complex wiring work and furthermore has a problem regarding user convenience because limitations apply to the arrangement of devices. For this reason, networks by means of radio have been gaining popularity as a means for further improvement of convenience, and technologies related to wireless LAN represented by IEEE 802.11b and wireless PAN (Personal Area Network) represented by Bluetooth, are being put into practical use.

Given this background, now, a communication scheme of transmitting pulse modulated signals using a wide frequency band, called “UWB” (Ultra Wide Band), has been gaining popularity as an art to provide faster data communication at low cost. With this “UWB,” transmission power is lowered to an extent where existing radio systems are not influenced, to make a substantially wide frequency band available for use and achieve channels of large capacity, thereby providing an advantage of enabling substantially high data transmission rates with little power. Radio transmission by this UWB includes an art of transmitting a pulse signal in which the spectrum components cover a wide band, into a radio frequency and transmitting the radio frequency.

In radio transmission of pulse signals, the phenomenon might occur where reflections and diffractions are produced by walls and obstacles that exist between the transmitting apparatus and the receiving apparatus and where therefore the same signal waves are received at the receiving apparatus via a plurality of channels. This propagation environment is referred to as “multipath propagation.” In this multipath propagation environment, signal waves (hereinafter “delayed pulses”) arrive at the receiving terminal with delay behind the first signal wave to arrive at the receiving apparatus (hereinafter the “main pulse”), and interfere with the main pulse and deteriorate the received quality.

Deterioration of received quality due to delayed pulses will be descried using FIG. 1 with reference to an example case of using on-off keying (“OOK”) modulation as a pulse modulation scheme. In on-off keying modulation, as shown with the transmission signal of FIG. 1, digital signals of “1's” and “0's” are transmitted depending on whether or not there is an on-pulse signal. The receiving end detects whether or not there are on-pulse signals in the symbol interval and performs demodulation.

Now, to imagine a propagation environment where one delayed pulse is produced a certain period of time later due to multipath propagation and other factors, a delayed pulse is produced every time an on-pulse signal representing data “1” is transmitted (i.e. a pulse signal in which the voltage value is not zero), and therefore these signals are received at the receiving end with delayed pulses. If a delayed pulse of a high amplitude level is produced in a wrong symbol interval, even if an off-pulse signal representing that the data in that symbol interval is “0” is transmitted (i.e. a pulse signal in which the voltage value is zero), there is nevertheless a possibility that the delayed pulse is detected and “0” is misidentified “1.” For example, in a case where transmission pulse signal S10 is transmitted and main pulse S20 of transmission pulse signal S10 and delayed pulse S21 of transmission pulse signal S10 arrive at the receiving apparatus, although the data transmitted from the transmitting end at the timing delayed pulse S21 is “0” and therefore an on-pulse signal is not transmitted, delayed pulse S21 is detected and consequently the value identified in this symbol interval is misidentified “1.” This error of misidentifying “1” for “0” is referred to as a “warning error” and deteriorates received quality.

Arts that are generally known to be directed to improving deterioration of received quality caused by multipath propagation, include the OFDM (Orthogonal Frequency Division Multiplex) scheme, which provides and transmits guard intervals where data partially overlaps in the time domain, and RAKE reception, which separates the desired signal from the received signal with delayed pulses superimposed thereupon by despreading processing, corrects the phase difference between the main pulse and delayed pulses and combines these signals to improve the received signal power, and these Arts are in practical use for mobile telephones and so on.

Furthermore, patent document 1 discloses an anti-delayed pulse technology that is different from the above common technologies. The art disclosed in patent document 1 is directed to solving a technical problem in pulse position modulation that a plurality of delayed pulses arriving at the receiving end widen the pulse width, make it difficult to identify positions, and, consequently, deteriorate received quality. The art disclosed in patent document 1 will be described with reference to FIG. 2. FIG. 2A shows transmission PPM (Pulse Position Modulation) signal S30 and received signals S31 to S34 of every two-bit symbol data. Four time slots are provided in a symbol interval, and transmission PPM signal S30 represents a symbol by allocating an on-pulse signal in only one time position. The receiving end receives at the same time received signal S31 and received signals S32 and S33 arriving late via different channels. Therefore, in reality, these are superimposed upon one another and received as signal S34. The pulse width in received signal S34 becomes wider than transmission PPM signal S30, and therefore there is a possibility that it becomes difficult upon demodulation to identify the positions where on-pulse signals are allocated and errors occur with one or two bits.

To solve this problem, according to the art disclosed in patent document 1, if there is a place where symbols “11” and symbols “00” continue, that is, a place where two positions where pulses are allocated abut one another, as shown in the dotted oval shape over transmission PPM signal S30 in FIG. 2B, the processing to narrow the pulse width to half is applied in advance and thereupon transmission signal S40 is generated. Then, at the receiving end, received signal S41 influenced by multipath propagation shown in FIG. 2C arrives. Like received signal S34 described above, the pulse width of received signal S41 is one time slot stretched backward due to delayed pulses. The art disclosed in patent documents 1 applies the process of repairing the pulse width that has stretched backward on the time axis and generates repaired signal S42. Furthermore, in the consecutive symbols in repaired signal S42, if an on-pulse signal is allocated in the last time slot in a given symbol interval and an on-pulse signal is not allocated anywhere in the following symbol interval, the width of the on-pulse signal allocated in the last time slot of the preceding symbol interval is stretched to the first time slot of the following symbol. By this means, as shown in the dotted oval shape in FIG. 2C, the pre-processing carried out at the transmitting end is undone, and, as a result, pulse signal S43 is acquired as the demodulated signal.

As described above, according to the art disclosed in patent document 1, by transmitting signals that are processed in advance taking into account the increase of the received pulse width due to delayed pulses and by undoing the processing at the receiving end, demodulation errors due to delayed pulses are prevented to improve received quality even when delayed pulses are produced due to the influence of multipath propagation. Patent Document 1: Japanese Patent Application Laid-Open No. 2004-229288

### Disclosure of Invention Problems to be Solved by the Invention

However, the OFDM scheme and RAKE reception, which are known as common anti-multipath propagation technologies, provide an excellent improvement effect but nevertheless requires high-level signal processing, which then give a rise to a problem of increased circuit scale and power consumption. In particular, considering application to UWB, these arts damage the advantage of UWB, namely its feasibility on the grounds of low power and cost, and therefore simpler anti-multipath propagation technologies are in demand.

Furthermore, although the transmitting and receiving apparatuses and transmitting and receiving methods disclosed in patent document 1 are effective if delay time is substantially shorter than the symbol interval, still, it is difficult to cope with a case where a delayed pulse interferes with symbols that are only several symbols apart, and it is more likely that high-speed pulse communication represented by UWB have difficulty proving effective. In addition, the art disclosed in patent document 1 is anti-delayed pulse only with respect to the pulse position modulation scheme and cannot be applied on an as-is basis to the on-off keying modulation scheme which can be implemented in a simpler manner.

The present invention is made in view of the foregoing and it is therefore an object of the present invention to provide a pulse transmitting apparatus, pulse receiving apparatus, pulse communication system and pulse communication method for preventing inter-pulse interference that is produced from the influence of multipath propagation and improving received quality by a relatively simple method.

### Means for Solving the Problem

Now, to achieve the above object, the pulse transmitting apparatus of the present invention employs a configuration having: a pulse generating means that generates a pulse according to data to be transmitted; an acquiring means that acquires a delay time, which a delayed pulse takes behind a main pulse to arrive at a communicating party; a non-use interval providing means that provides a non-use interval, in which a pulse is not transmitted, based on the delay time; a pulse position adjusting means that adjusts a pulse position of the pulse such that the pulse is not transmitted in the non-use interval; and a radio transmitting means that transmits a pulse signal, the pulse signal comprising the pulse, which is converted to a radio frequency band in a pulse position adjusted by the pulse position adjusting means.

According to this configuration, when an on-pulse signal produces delayed pulses of non-zero power values due to multipath propagation, non-use intervals are provided such that subsequent pulses do not arrive at timings delayed pulses of the on-pulse signal arrive at the communicating party, so that it is possible to prevent delayed pulses of an on-pulse signal and subsequent pulses from arriving at the communicating party superimposing upon one another and reduce inter-pulse interference produced due to the influence of multipath propagation.

### ADVANTAGEOUS EFFECT OF THE INVENTION

The present invention makes it possible to prevent inter-pulse interference that is produced by the influence of multipath propagation by a relatively simple method and improve received quality even in high speed pulse transmission represented by UWB.

### BRIEF DESCRIPTION OF DRAWINGS

FIG. 1 shows conventional relationships between transmission data, transmission timings and receiving timings;

FIG. 2A shows the relationships between transmission timings of pulse position modulated signals and receiving timings of received signals on multipath propagation channels;

FIG. 2B shows the relationships between the waveforms of a pulse position modulated signal and a conventional transmission signal and their transmission timings;

FIG. 2C shows the relationships between the waveforms of a conventional received signal and demodulated signal and their transmitting and receiving timings;

FIG. 3 is a block diagram showing primary configurations of the pulse transmitting apparatus according to embodiment 1 of the present invention;

FIG. 4 shows the timing relationships between symbol intervals Ts and non-use intervals Tb;

FIG. 5 is a block diagram showing primary configurations of the pulse receiving apparatus according to embodiment 1;

FIG. 6 shows transmitting timings and receiving timings;

FIG. 7 is a flowchart for explaining the operations of the pulse transmitting apparatus according to embodiment 1;

FIG. 8 is a flow chart for explaining the operations of the pulse receiving apparatus according to embodiment 1;

FIG. 9 shows the timings the main pulses and delayed pulses arrive, according to embodiment 1;

FIG. 10 shows the timings the main pulses and delayed pulses arrive in a case where non-use intervals are not provided;

FIG. 11 is a block diagram showing other primary configurations of the pulse transmitting apparatus according to embodiment 1;

FIG. 12 shows the relationships between transmission data bit transitions, differential flags “diff,” non-use intervals “Tb” and time durations “Tf”;

FIG. 13 shows the timings the main pulses and delayed pulses arrive, according to embodiment 1;

FIG. 14 is a block diagram showing primary configurations of the pulse receiving apparatus according to embodiment 1;

FIG. 15 shows a symbol interval Ts and the timings the main pulse and a delayed pulse arrive, according to embodiment 2 of the present invention;

FIG. 16 shows the timing relationships between transmission data a radio pulse modulated signals according to embodiment 2;

FIG. 17 shows the timings the main pulses and delayed pulses arrive and demodulation results in each symbol interval Ts according to embodiment 2; and

FIG. 18 shows the relationships between transmission data, transmission timings, receiving timings, pulse identification results and demodulated data.

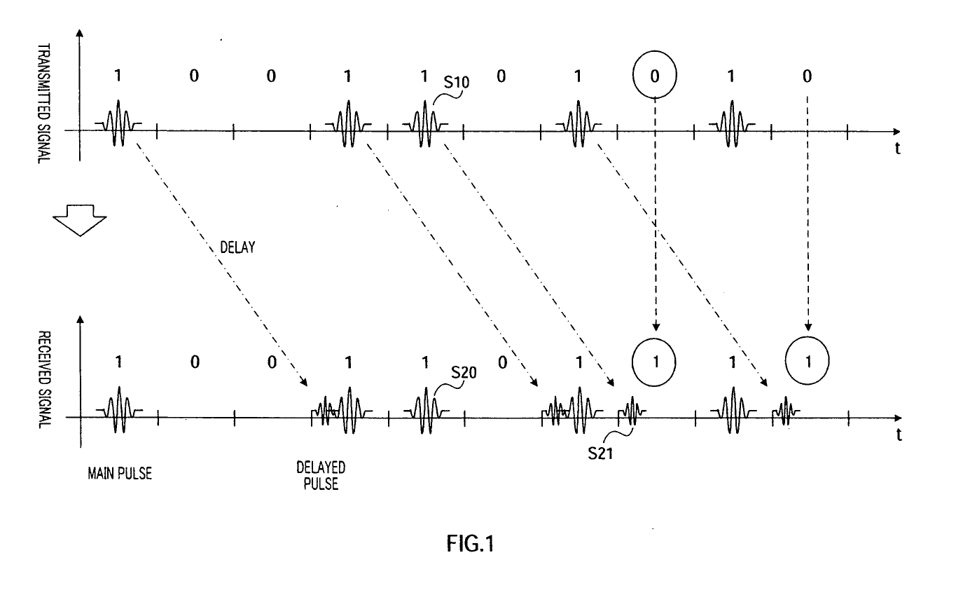

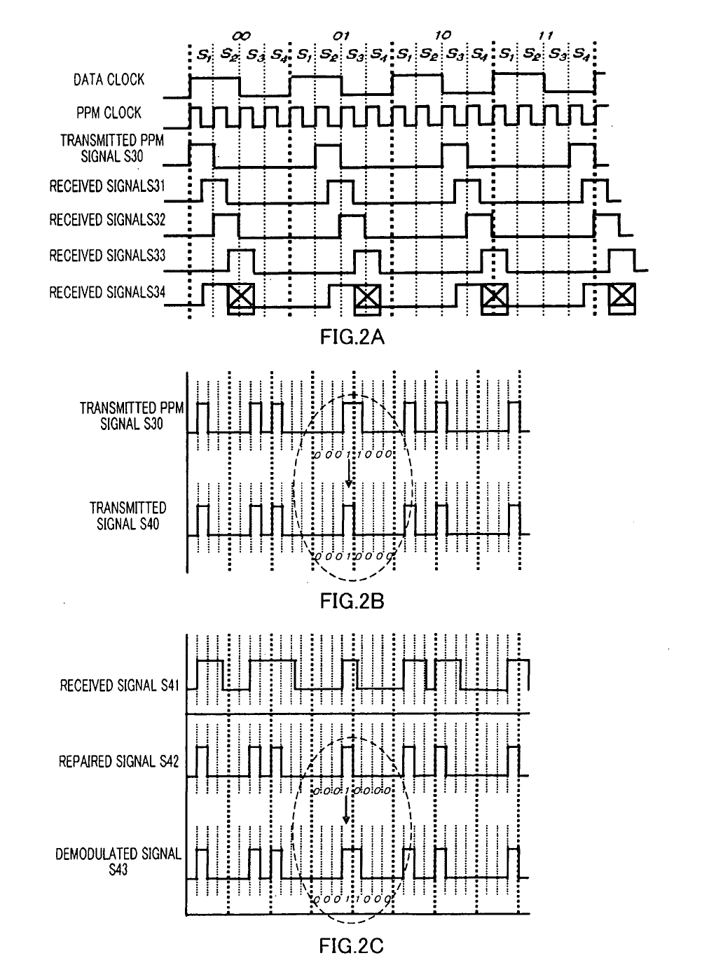

### BEST MODE FOR CARRYING OUT THE INVENTION

Now, embodiments of the present invention will be described below in detail with reference to the accompanying drawings.

### Embodiment 1

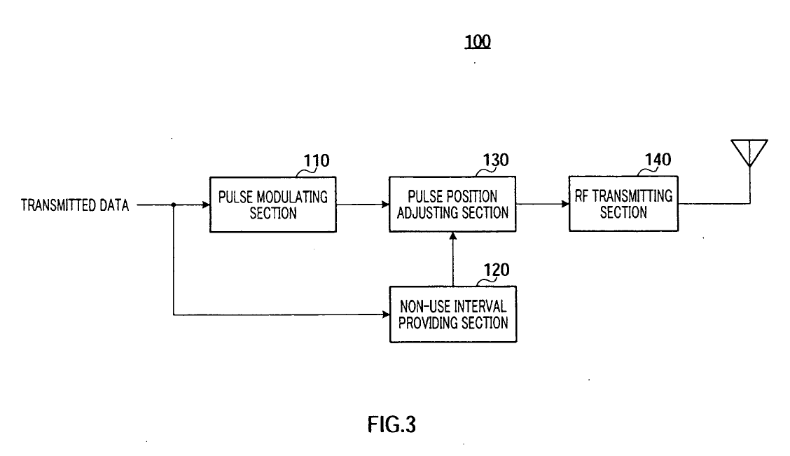

FIG. 3 shows primary configurations of the pulse transmitting apparatus according to the present embodiment.

Pulse transmitting apparatus 100 shown in FIG. 3 has pulse modulating section 110, non-use interval providing section 120, pulse position adjusting section 130, and RF transmitting section 140.

Pulse modulating section 110 generates, depending on transmission data, either a pulse of a zero voltage value (hereinafter an “off-pulse signal”) or a pulse of a non-zero voltage value (hereinafter an “on-pulse signal”). In the case described below, pulse modulating section 110 performs OOK modulation, generating an on-pulse signal when transmission data is “1” and generating an off-pulse signal when transmission data is “0.” Messages may include text, video, images, audio and so on, or combinations of these. Incidentally, in OOK modulation, it is equally possible to generate an on-pulse signal when transmission data is “0” and generate an off-pulse signal when transmission data is “1,” as long as the method of allocating on and off pulse signals and transmission data is shared between the transmitting end and the receiving end.

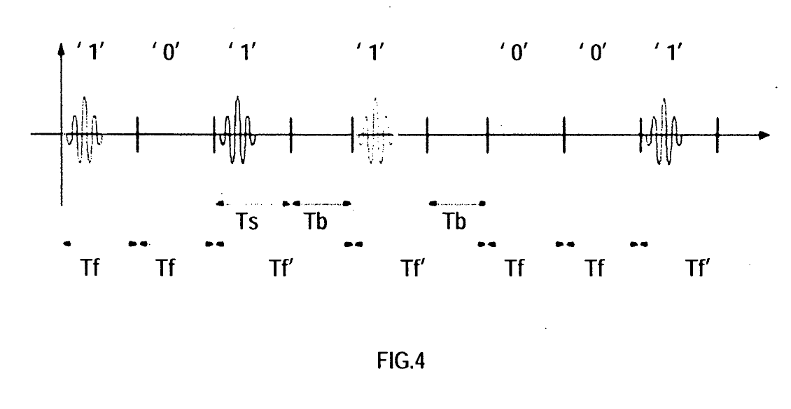

Depending on transmission data, non-use interval providing section 120 inserts non-use intervals Tb in which pulses are not generated. FIG. 4 shows the relationships between transmission data symbol intervals Ts (also referred to as “symbol intervals”) and non-use intervals Tb. To be more specific, only when transmission data is “1,” non-use interval providing section 120 provides a non-use interval Tb immediately after the symbol interval Ts for the transmission data. As will be described later, pulse positions are adjusted by pulse position adjusting section 130 such that pulses are not transmitted in non-use intervals Tb. Consequently, the time duration Tf that is allocated when transmission data is “1” becomes long compared to the time duration Tf′ allocated when transmission data is “0.” Then, non-use intervals Tb are provided such that the time duration Tf′, that is, the total time of a predetermined symbol interval Ts and a non-use interval Tb, is the same value as the average multipath propagation delay time D or a greater value than the average multipath propagation delay time D. As a result of this, the main pulse of an on-pulse signal or off-pulse signal arrives at the receiving end without having delayed pulses superimposed thereupon, so that the influence of inter-pulse interference can be prevented. Non-use interval providing section 120 memorizes inside the non-use intervals Tb provided, and outputs the same to pulse position adjusting section 130. The method of finding average delay time D will be described later.

Depending on the non-use intervals Tb memorized in non-use interval providing section 120, pulse position adjusting section 130 adjusts the position where the i-th pulse symbol starts (where i is a natural number). To be more specific, if the (i−1)-th transmission data is “1” and a non-pulse interval Tb is provided by non-use interval providing section 120, pulse position adjusting section 130 adjusts pulse positions such that the point in time a symbol interval Ts and a non-use interval Tb after the position the (i−1)-th pulse symbol starts, is the position where the i-th pulse symbol starts. Furthermore, if the (i-1)-th transmission data is “0” and a non-use interval Tb is not provided by non-use interval providing section 120, pulse position adjusting section 130 adjusts pulse positions such that the point in time a symbol interval Ts after the position the (i−1)-th pulse symbol starts, is the position where the i-th pulse symbol starts. Pulse position adjusting section 130 adjusts pulse positions such that neither an on-pulse signal nor an off-pulse signal is transmitted in a non-use interval Tb. Pulse position adjusting section 130 outputs pulses in adjusted pulse positions, to RF transmitting section 140.

If a pulse outputted from pulse position adjusting section 130 is anon-pulse signal, RF transmitting section 140 performs predetermined radio transmission processing upon the on-pulse signal and generates a radio pulse modulated signal. To be more specific, radio modulated signal is generated by, for example, up-conversion using a local oscillation signal and switching on and off an oscillator that oscillates radio frequency signals. RF transmitting section 140 amplifies the radio pulse modulated signal to adequate transmission power and transmits the signal into the air via an antenna.

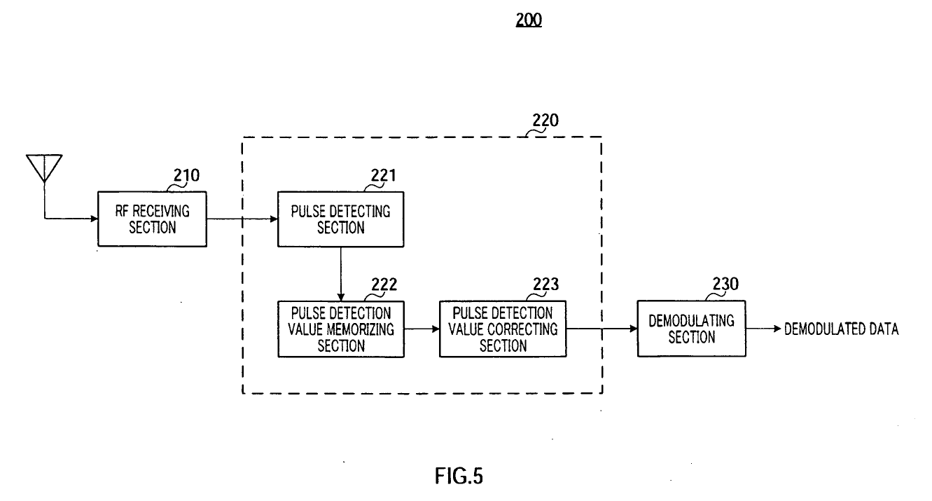

FIG. 5 shows primary configurations of pulse receiving apparatus 200 according to the present invention. Pulse receiving apparatus 200 shown in FIG. 5 has RF receiving section 210, pulse identifying section 220 and demodulating section 230. Pulse identifying section 220 is comprised of pulse detecting section 221, pulse detection value memorizing section 222 and pulse detection value correcting section 223.

RF receiving section 210 performs predetermined radio receiving processing (i.e. down-conversion, amplification processing, band-limiting processing, etc.) and converts the radio pulse modulated signal into a baseband signal. The radio pulse modulated signal is an OOK modulated signal, so that, for its frequency-domain conversion into a base band signal, envelope detection by a diode detector, which has a relatively simple configuration, may be used.

Pulse detecting section 221 samples the baseband signal outputted from RF receiving section 210 at time intervals of 1/M of the symbol interval Ts (where M is an integer) and detects whether or not there is an on-pulse signal. For example, threshold comparison using a comparator may be performed to detect whether or not there is an on-pulse signal.

Pulse detection value memorizing section 222 is comprised of, for example, shift registers and memories, employing a configuration whereby pulse detection results outputted from pulse detecting section 221 are memorized over a predetermined period of time in manner these results can be checked. The duration of time to memorize pulse detection results is at least the difference between the times a main pulse and delayed pulses of the main pulse arrive at the receiving end, that is, the delay time or more.

When a pulse detection result memorized in pulse detection value memorizing section 222 is “1” and an on-pulse signal is detected, pulse detection value correcting section 223 checks the pulse detection result in the non-use interval Tb associate with the on-pulse signal, and, if the pulse detection result in the non-use interval Tb is “1,” corrects this pulse detection result to “0.” Only when transmission data is “1,” non-use interval providing section 120 of pulse transmitting apparatus 100 provides a non-use interval Tb immediately after the symbol interval Ts for the transmission data, and pulse position adjusting section 130 adjusts pulse positions such that neither an on-pulse signal nor an off-pulse signal is transmitted in the non-use interval Tb. When a pulse detection result memorized in pulse detection value memorizing section 222 is “1,” by principle, a pulse must not have been transmitted in the non-use interval Tb associated with the on-pulse signal and therefore the pulse detection result in the non-use interval Tb is supposed to be “0.” However, if pulse detection is performed wrong due to the influence of noise and such and a pulse is detected to be present in the non-use interval Tb, as described above, pulse detection value correcting section 223 is able to correct the pulse detection result to “0” and correct the wrong pulse detection result produced due to the influence of noise.

Demodulating section 230 extracts the detection result in the symbol interval from the pulse detection result corrected by pulse detection value correcting section 223, and demodulates the transmission data.

As described above, according to the present embodiment, non-use intervals Tb are provided such that the total time of a predetermined symbol interval Ts and a non-use interval Tb is the same value as the average multipath propagation delay time D or a greater value than the average multipath propagation delay time D, so that main pulse and delayed pulses arrive at the receiving end without superimposing upon one another and by this means the influence of inter-pulse interference is prevented. Consequently, upon providing non-use intervals Tb, information about average multipath propagation delay time D is necessary and needs to be shared between the transmitting end and the receiving end.

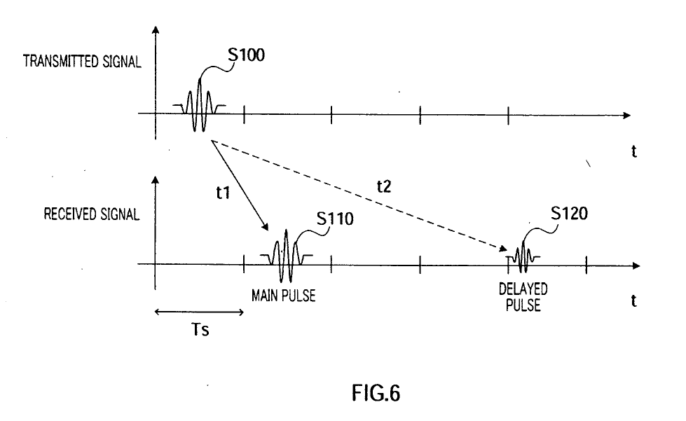

The average multipath propagation delay time D is found in the following manner, for example. FIG. 6 is a timing chart showing waveforms in a case where a single on-pulse signal S100 is transmitted from pulse transmitting apparatus 100 and arrives at pulse receiving apparatus 200 via the propagation channel. After the propagation delay time t1, on-pulse signal S100 arrives at pulse receiving apparatus 200 as main pulse S110, and, reflected by obstacles such as walls, arrives at pulse receiving apparatus 200 as delayed pulse S120 the propagation delay time t2 later. Pulse receiving apparatus 200 receives these main pulse S110 and delayed pulse S120, performs pulse detection by sampling these received signals at a frequency equal to or above the symbol rate, and acquires the delay time between main pulse S110 and delayed pulse S120 from the sampling frequency of the sample points in which pulses are detected. Pulse receiving apparatus 200 reports information about the delay time acquired, to pulse transmitting apparatus 100 using the transmission mechanism provided inside. The delay time is required upon providing non-use intervals Tb and therefore needs to be reported to pulse transmitting apparatus 100 reliably by, for example, lowering the transmission rate, increasing the transmission power and using a modulation method that achieves a better signal-to-noise ratio.

In the actual propagation environment, there are a number of obstacles of complex shapes and cases may occur where there are three propagation channels and several delayed pulses are produced. However, even when there are a plurality of delayed pulses, it is likewise possible to learn the delay time of each delayed pulse, and, by reliably reporting information acquired with regards to the delay time to pulse transmitting apparatus 100, optimal values can be provided for non-use intervals Tb. However, if the number of delayed pulses increase, the amount of calculation also increases, in which case it is possible to compare the received levels of delayed pulses to a predetermined threshold and calculate the delay time only with respect to delayed pulses greater than the threshold value, so that it is not necessary to calculate the delay time of all delayed pulses.

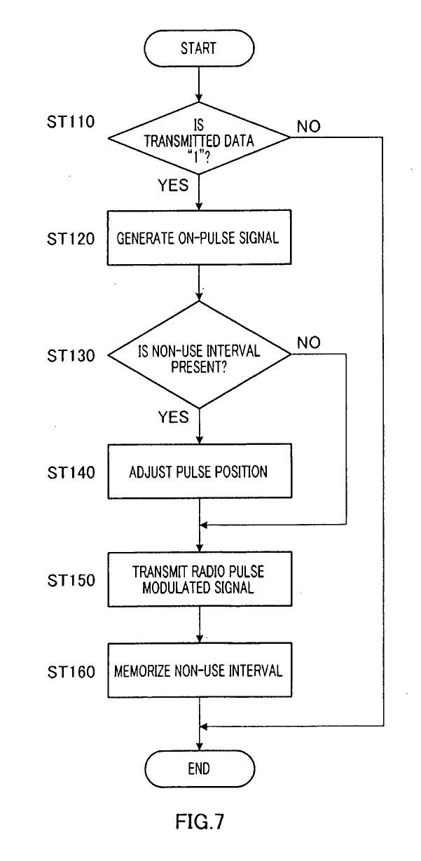

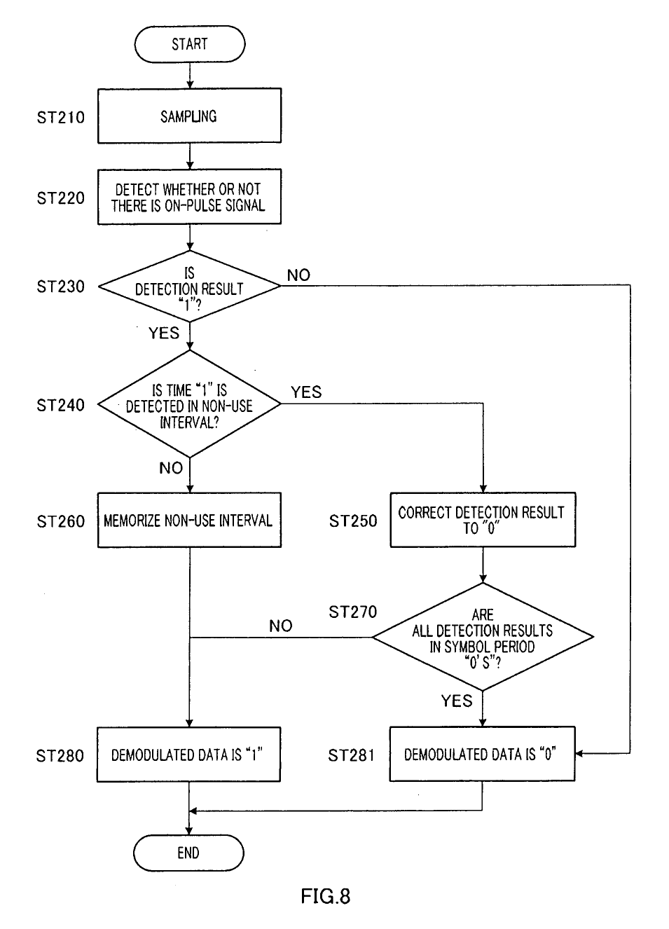

Next, the operations of pulse transmitting apparatus 100 and receiving apparatus 200 configured like above will be described with reference to the flowcharts of FIG. 7 and FIG. 8.

First, pulse modulating section 110 generates pulse modulated signals by on-off keying (OOK) modulation scheme based on transmission data. The OOK modulation scheme refers to an amplitude shift keying (ASK) modulation scheme of a modulation level 100%, transmitting digital signals of “1's” and “0's” represented by whether or not there are on-pulse signals. That is to say, whether or not transmission data is “1” is decided (ST 110), and, if transmission data is “1,” pulse modulating section 110 generates an on-pulse signal (ST 120).

Non-use interval providing section 120 provides intervals where pulses are not generated, that is, provides non-use intervals Tb. To be more specific, if transmission data is “1,” that is, if an on-pulse signal is allocated, non-use interval providing section 120 provides a non-use interval Tb immediately after a predetermined symbol interval Ts. Non-use intervals Tb are provided then such that the total time of a predetermined symbol interval Ts and a non-use interval Tb is the same value as the average multipath propagation delay time D or a greater value than the average multipath propagation delay time D. As a result of this, the main pulse and delayed pulses arrive at the receiving end without superimposing upon one another and the influence of inter-pulse interference is prevented. The non-use intervals provided thus are memorized in non-use interval providing section 120.

Pulse position adjusting section 130 adjusts the position the i-th pulse symbol starts, based on information about the non-use intervals Tb memorized in non-use interval providing section 120. To be more specific, if the (i−1)-th transmission data is “1” and a non-use interval Tb is provided by non-use interval providing section 120 (“YES” in ST 130), pulse position adjusting section 130 adjusts pulse positions such that the point in time a symbol interval Ts and a non-use interval Tb after the position the (i−1)-th pulse symbol starts, is the position where the i-th pulse symbol starts (ST 140). On the other hand, if the (i−1)-th transmission data is “0” and a non-use interval Tb is not provided by non-use interval providing section 120 (“NO” in ST 130), pulse position adjusting section 130 adjusts pulse positions such that the point in time a symbol interval Ts after the position the (i−1)-th pulse symbol starts, is the position where the i-th pulse symbol starts. Then, if the i-th pulse is an on-pulse signal, RF transmitting section 140 performs radio transmission processing and transmits a radio pulse modulated signal (ST 150).

Then, non-use interval providing section 120 memorizes the non-use intervals Tb matching the transmission start timing for the radio pulse modulated signal really transmitted (ST 160). This non-use interval Tb memorized in non-use interval providing section 120 (i+1) determines the timing the (i+1)-th pulse starts.

The steps ST 110 to ST 160 described above are repeated, pulse positions are adjusted as needed, and radio pulse modulated signals are transmitted to pulse receiving apparatus 200 of the communicating party.

A radio pulse modulated signal transmitted from pulse transmitting apparatus 100 arrived at pulse receiving apparatus 200 via multipath propagation channels.

The radio pulse modulated signal received via the antenna is subjected to predetermined radio receiving processing and transformed into a baseband signal.

Pulse detecting section 221 samples the baseband signal (ST 210) and detects by threshold comparison whether or not there is anon-pulse signal (ST 220). Then, pulse detection value correcting section 223 checks whether or not the pulse detection results are “1” following the time sequence order (ST 230), and, if the presence of an on-pulse signal is detected and the pulse detection result is “1,” identifies whether or not time “1” is detected is inside a non-use interval Tb (ST 240). Only if the time “1” is detected is within a non-use interval Tb, is the pulse detection result is corrected to “0” (ST 250). That is to say, at the transmitting end, if an on-pulse signal is generated in a symbol interval Ts, a non-use interval Tb is provided to continue from the symbol interval Ts so as not to generate a pulse in the non-use interval Tb. Consequently, even when a delayed pulse is received and a wrong decision is made in the non-use interval Tb that an on-pulse signal is present, it is possible to correct the pulse detection result to the correct value and reduce the deterioration of received quality.

From the pulse detection result corrected in pulse detection value correcting section 223, demodulating section 230 extracts the pulse detection results in symbol intervals Ts (ST 270) and demodulates the transmission data. To be more specific, if the pulse detection results in symbol intervals Ts are all “0's,” “0” is acquired as the demodulated data (ST 281). On the other hand, if “1” is included in the detection results in symbol intervals Ts, “1” is acquired as the demodulated data (ST 280).

Then, the non-use interval Tb for the symbol interval Ts in which “1” is acquired as the demodulated data, is memorized in pulse detection value correcting section 223.

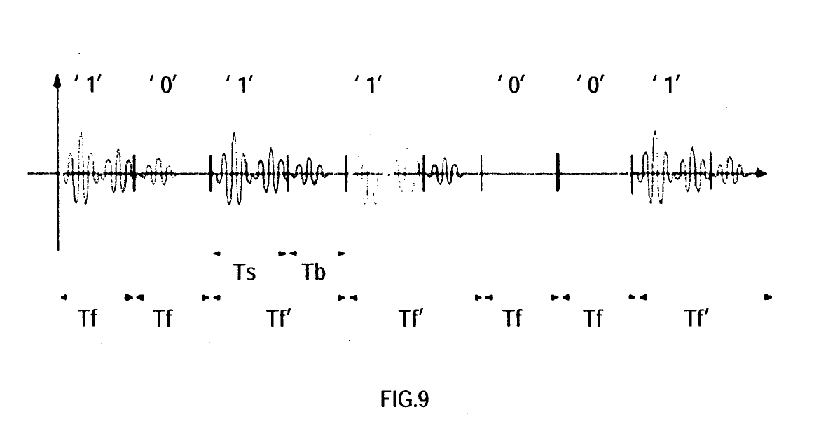

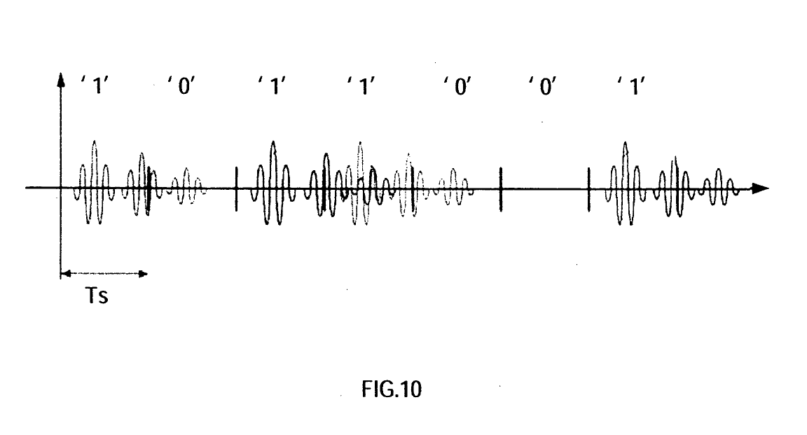

FIG. 9 shows a timing chart showing the main pulses and delayed pulses transmitted by pulse transmitting apparatus 100 and arriving at the receiving end. FIG. 9 illustrates a case where the value of a non-use interval Tb is to such a value the total time of a predetermined symbol interval Ts and a non-use interval Tb is the same value as the average delay time D or a greater value than the average delay time D, so that main pulses and delayed pulses arrive at the receiving end without superimposing upon one another and the influence of inter-pulse can be prevented. On the other hand, if a non-use interval Tb is not provided, as shown in FIG. 10, main pulses and delayed pulses arrive at the communicating party superimposing upon one another, thus producing inter-pulse interference.

As described above, according to the present embodiment, a non-use interval Tb in which no pulse is transmitted is provided immediately after an on-pulse signal is transmitted, taking into account the delay time of delayed pulses arriving after the main pulse due to multipath propagation, so that it is possible to reliably prevent inter-pulse interference that is produced when the main pulse and delayed pulses arrive at the receiving end at the same time, and, as a result, prevent deterioration of received quality in the multipath propagation environment.

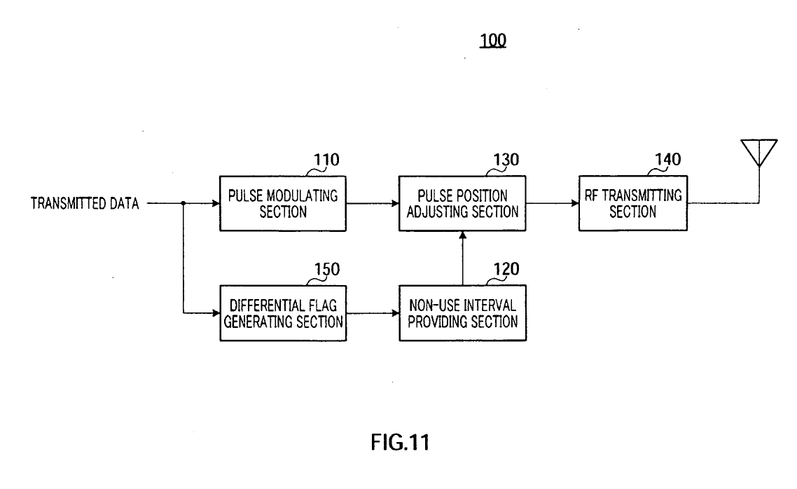

In the example described above, non-use interval providing section 120 provides a non-use interval Ts after every symbol interval Ts if transmission data is “1” and an on-pulse signal is generated. However, if transmission data transitions from “1” to “1,” that is, if on-pulse signals are generated in consecutive symbol intervals Ts, a non-use interval Tb may be inserted between these symbol intervals Ts. FIG. 11 shows primary configurations of pulse transmitting apparatus 100 in this case. By contrast with FIG. 3, pulse transmitting apparatus 100 shown in FIG. 11 employs a configuration with an addition of transmitting differential flag generating section 150.

Differential flag generating section 150 generates differential flags depending on the transitions of transmission data, and outputs the differential flags to non-use interval providing section 120. To be more specific, differential flag generating section 150 generates “1” as a differential flag if transmission data is followed by “1,” and, otherwise, generates, “0” as a differential flag, and outputs these flags to non-use interval providing section 120. Although not illustrated in FIG. 11, a differential flag is transmitted by RF transmitting section 140 and reported to the communicating party.

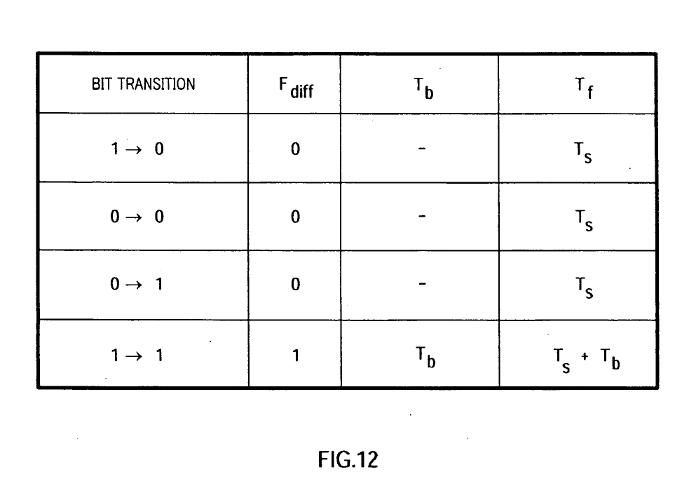

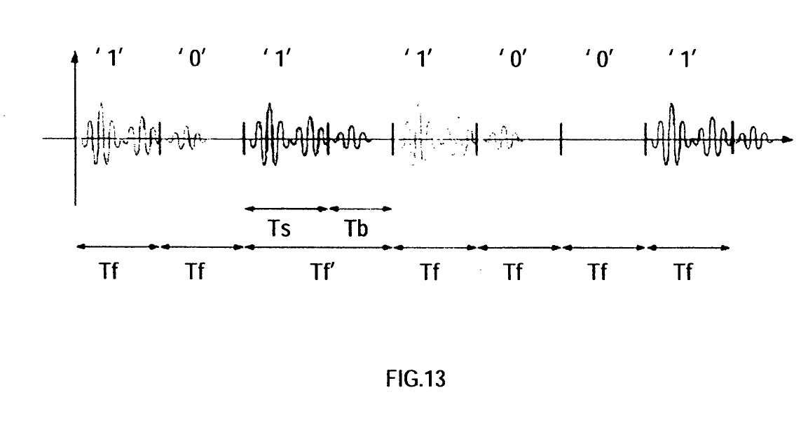

Depending on differential flags, non-use interval providing section 120 provides non-use intervals Tb. To be more specific, only when a differential flag for “1” is presented, that is, only when transmission data is followed by “1,” a non-use interval Tb is provided. FIG. 12, in which, when on-pulse signals are transmitted in consecutive symbol intervals, a non-use interval is provided between these symbol intervals, shows the relationships between transmission data bit transitions, differential flags Fdiff, non-use intervals Tb and time durations Tf. FIG. 13 shows a timing chart of main pulses and delayed pulses arriving at the receiving end. FIG. 13 makes it clear that, when transmission data is followed by “1” and on-pulse signals therefore continue being generated, it is possible to prevent inter-pulse interference produced between the main pulses and delayed pulses of the on-pulse signals generated for the transmission data “1,” by providing a non-use interval between the on-pulse signals. Furthermore, a non-use interval Tb is provided only when transmission data is followed by “1” and on-pulse signals therefore continue being transmitted, so that it is possible to reduce the proportion of time pulses cannot be transmitted compared to the case shown in FIG. 9 where a non-use interval Tb is provided for every transmission data “1,” and, as a result, minimize the decrease of data throughput caused by providing non-use intervals Tb.

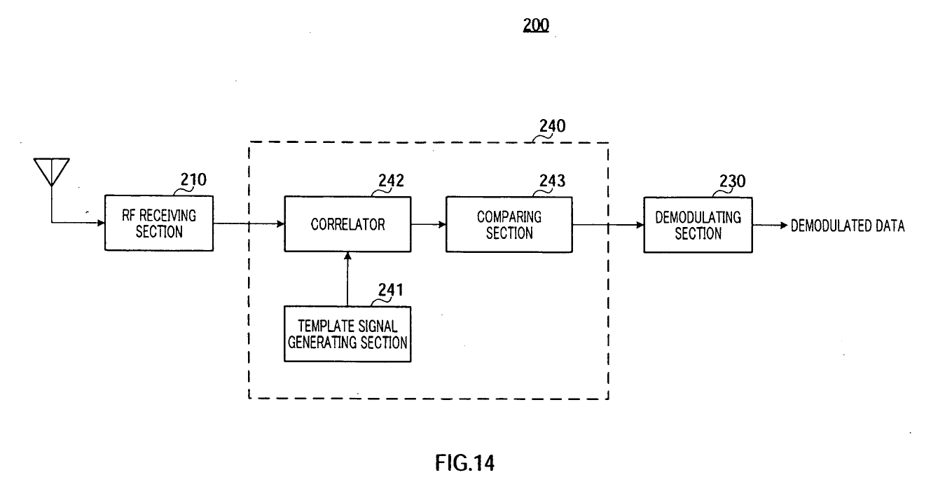

FIG. 14 is a block diagram showing primary configurations of pulse receiving apparatus 200 receiving radio pulse modulated signals transmitted in which a non-use interval is inserted only when a differential flag for “1” is presented. Compared to FIG. 5, FIG. 14 shows a configuration in which pulse identifying section 220 is removed and pulse identifying section 240 is added. Pulse identifying section 240 has template signal generating section 241, correlator 242 and comparing section 243.

Template signal generating section 241 generates a pulse template signal for performing correlation calculation with the received signal subjected to radio receiving processing in RF receiving section 210, and outputs the pulse template signal to correlator 242.

Correlator 242 acquires information about the variable bit time duration Tf of each bit based on differential flags, Fdiff, reported from pulse transmitting apparatus 100, determines the positions the correlation processing for each bit starts, and, furthermore, acquires the correlation between the received signal and the template signal outputted from template signal generating section 241, and acquires baseband signals. Correlator 242 includes a filter, and this filter performs functions as a multiplier, functions as an integrator, and performs the role of optimizing the signal to noise ratio (SNR).

Comparing section 243 compares the baseband signals with a predetermined threshold value and outputs baseband signals greater than the threshold value to demodulating section 230.

Demodulating section 230 identifies between “0” and “1” based on the baseband signals outputted from comparing section 243, and acquires the transmission data.

By this means, only when the transmission data bit transitions from “1” to “1” and on-pulse signals are generated in consecutive symbol intervals Ts, a non-use interval Tb is provided between these symbol intervals Ts, so that, by proving a non-use interval between the symbol intervals Ts, it is possible to minimize the interval pulses cannot be transmitted, minimize the decrease in data throughput and prevent the influence upon inter-pulse interference.

### Embodiment 2

Embodiment 1 has been shown above to provide non-use interval Tb in a proportion equal to the delay time immediately after a symbol interval Ts in which symbol interval Ts is generated and adjust pulse positions such that pulses are not transmitted in the non-use interval Tb, to make the main pulse and delayed pulses not arrive at the receiving end at the same time. However, if a symbol interval Ts is several nanoseconds, the average multipath propagation delay time D becomes substantially longer than the symbol interval Ts. Consequently, if non-use intervals are provided in an equal proportion to the delay time immediately after a symbol interval Ts in which an on-pulse signal is generated, the proportion of time in which pulses cannot be transmitted increases and data throughput decreases. With the present embodiment, therefore, only parts in time when delayed pulses arrive at the receiving end is provided non-use intervals Tb.

Primary configurations in the pulse transmitting apparatus and pulse receiving apparatus according to the present embodiment are the same as in embodiment 1 (i.e. see FIG. 3 and FIG. 5) and therefore their descriptions will be omitted. That is, the pulse transmitting apparatus according to the present embodiment is different from embodiment 1 in the method of providing non-use intervals Tb in non-use interval providing section 120 and in the method of pulse position adjustment in pulse position adjusting section 130.

Furthermore, assume that information about the delay time of the main pulse and delayed pulses arriving at pulse receiving apparatus 200 of the communicating party is reported in advance from pulse transmitting apparatus 100 to pulse receiving apparatus 200 as in embodiment 1. Furthermore, pulse transmitting apparatus 100 according to the present embodiment divides a symbol interval Ts into three time slots (i.e. Ts 1, Ts 2 and Ts 3), selects one of the time slots Ts 1 to Ts 3 in the symbol time slot Ts, and transmits a pulse at the timing of the selected time slot. The time width ΔT of Ts 1 to Ts 3 secures the same time width as the time width of the pulse or a longer time width than that.

Non-use interval providing section 120 provides a non-use interval Tb at the timing the delay time after the timing an on-pulse signal starts being transmitted, and memorizes the timing the non-use interval Tb starts.

Pulse position adjusting section 130 adjusts the transmission timing of pulse signals such that pulses are not transmitted in the non-use interval Tb memorized in non-use interval providing section 120.

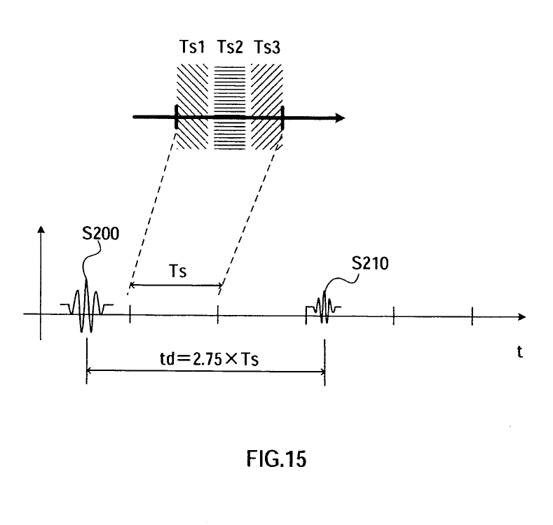

The operations of pulse transmitting apparatus 100 and receiving apparatus 200 configured like above will be described now in detail with reference to the accompanying drawings. A case will be assumed and explained below where, as shown in FIG. 15, a radio pulse modulated signal for transmission data “1,” transmitted from the transmitting end, arrives at the receiving end via the shortest channel as main pulse S200, and arrives at the receiving end via another channel as delayed pulse S210, with a delay 2.75 times the symbol interval Ts behind main pulse S200.

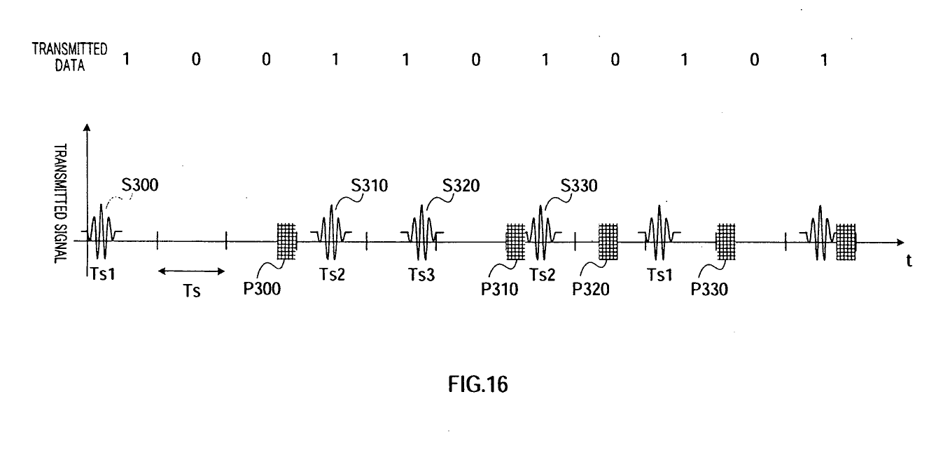

FIG. 16 shows the timing relationships between transmission data and radio pulse modulated signals. First, for the first transmission data “1,” pulse modulating section 110 generates on-pulse signal S300 and allocates on-pulse signal S300 in an arbitrary one of time slots Ts 1 to Ts 3. FIG. 16 shows the situation where on-pulse signal S300 is allocated in time slot Ts 1.

Based on the position on-pulse signal S300 starts, non-use interval providing section 120 provides a non-use interval Tb after 2.75 Ts from the starting position of on-pulse signal S300. 2.75 Ts is a period of time that equals the delay time. In FIG. 16, P (Protect) 300 is the non-use interval Tb provided in association with on-pulse signal S300. The non-use interval Tb provided (P 300) is memorized in non-use interval providing section 120.

For the following transmission data “0” “0,” pulse modulating section 110 does not generate an on-pulse signal, so that non-use interval providing section 120 does not provide a non-use interval Tb.

For the following transmission data “1,” pulse modulating section 110 generates on-pulse signal S310. Then, pulse position adjusting section 130 adjusts the transmission timing of pulse signals such that on-pulse signal S310 is not transmitted in non-use interval Tb memorized in non-use interval providing section 120. That is, if anon-use interval Tb is provided in the symbol interval Ts of on-pulse signal S310, pulse position adjusting section 130 allocates on-pulse signal S310 avoiding this non-use interval Tb. In the example shown in FIG. 16, a non-use interval Tb is provided within a symbol interval Ts for transmission data “1,” so that an arbitrary position is selected from time slots Ts 1 to Ts 3 and on-pulse signal S310 is allocated. Taking into account that, if a large number of identical time slots are used to transmit radio pulse modulated signals, amplified spectrum components are produced due to the cycle of pulse repetitions, in FIG. 16, on-pulse signal S310 is arranged in a different time slot (Ts 2) from time slot Ts 1 in which on-pulse signal S300 is previously allocated.

Then, similar to on-pulse signal S300, based on the starting position of on-pulse signal S310, non-use interval providing section 120 provides a non-use interval Tb after 2.75 Ts from the starting position of on-pulse signal S310. In FIG. 16, P310 is the non-use interval Tb that is provided in association with on-pulse signal S310.

The non-use interval Tb provided (P 310) is memorized in non-use interval providing section 120.

For the following transmission data “1,” pulse modulating section 110 generates on-pulse signal S320. Similar to the case of on-pulse signal S310, the non-use interval Tb is not provided in the symbol interval Ts for the transmission data “1,” so that an arbitrary position is selected from time slots Ts 1 to Ts 3 and on-pulse signal S320 is allocated. Taking into account that, if a large number of identical time slots are used to transmit radio pulse modulated signals, amplified spectrum components are produced due to the cycle of pulse repetitions, in FIG. 16, on-pulse signal S310 is arranged in a different time slot (Ts 3) from time slot Ts 1 and Ts 2 in which on-pulse signal S300 and S310 are previously allocated.

Similar to on-pulse signals S300 and S310, based on the starting position of on-pulse signal S320, non-use interval providing section provides a non-use interval Tb after 2.75 Ts from the starting position of on-pulse signal S320. In FIG. 6, P320 is the non-use interval Tb provided in association with on-pulse signal S320. The non-use interval Tb provided (P320) is memorized in non-use interval providing section 120.

For the following transmission data “0,” an on-pulse signal is not generated, and for the following data “1,” pulse modulating section 110 generates on-pulse signal S330. Then, provided that a non-use interval Tb (P310) is present in time slot Ts 1 in the symbol interval TS, one of time slot Ts 2 and time slot Ts 3 is selected and on-pulse signal S330 is allocated therein. Furthermore, based on the starting position of on-pulse signal S330, non-use interval providing section 120 provides a non-use interval Tb after 2.75 Ts from the starting position of on-pulse signal S330. In FIG. 6, P330 is the non-use interval Tb provided in association with on-pulse signal S330. The non-use interval Tb provided (P330) is memorized in non-use interval providing section 120.

The same steps are repeated on, and distributed allocation is performed with Ts 1 to Ts 3 such that the positions on-pulse signals are allocated are distributed and non-use intervals Tb are provided according to the pulse allocation positions of on-pulse signals.

As described above, a symbol interval Ts is divided into several time slots and a non-use interval Tb is provided after the delay time a delayed pulse of an on-pulse signal takes to arrive behind the main pulse, so that it is possible to manage time adjustment and so on in time slot units, and, as a result, process the adjustment of pulse positions in a discrete manner and make implementation more convenient.

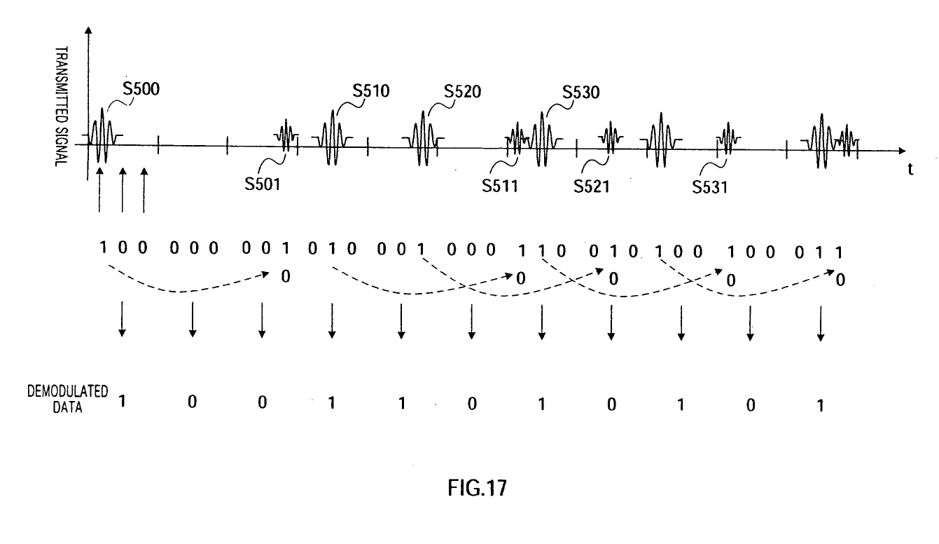

By this means, radio pulse modulated signals in adjusted pulse positions are transmitted from pulse transmitting apparatus 100 and arrive at the pulse receiving apparatus 200 of the communicating party. FIG. 17 is a timing diagram showing together radio pulse modulated signals arriving at pulse receiving apparatus 200 (i.e. main pulses and delayed pulses) and demodulation data of each symbol interval Ts. In FIG. 17, the horizontal axis is time and the divisions on the time axis mark symbol intervals Ts.

FIG. 17 makes it clear that main pulses S500, S510, S520 and S530 of on-pulse signals transmitted from pulse transmitting apparatus 100, and, in addition, delayed pulses S501, S511, S521 and S531 of the main pulses, arrive at pulse receiving apparatus 200. As described above, a case is assumed here where a delayed pulse arrives at pulse receiving apparatus 200 with a delay 2.75 times the symbol interval Ts after the main pulse.

Radio pulse modulated signals are demodulated as follows. First, pulse detecting section 221 samples a radio pulse modulated signal at a frequency three times the symbol transmission rate. This is done so because at the transmitting end a symbol interval Ts is divided into three time slots (Ts 1, Ts 2 and Ts 3) at the transmitting end and pulses are allocated by selecting between the time slots, so that faster sampling needs to be performed in pulse detecting section 221 when a symbol interval Ts is divided even smaller. With the present embodiment, pulse detecting section 221 detects three pulse detection results per symbol interval Ts. Pulse detection results are memorized in pulse detection value memorizing section 222.

Pulse detection value correcting section 223 corrects the pulse detection results. To be more specific, if a time where “1” is detected coincides with a non-use interval Tb provided in association with a time where “1” is detected earlier, the pulse detection result is corrected from “1” to “0.” For example, referring to FIG. 17, the time on-pulse signal S501 is received coincides with the non-use interval Tb provided in association with on-pulse signal S500, and so the pulse detection result with on-pulse signal S501 is corrected from “1” to “0.” Similarly, the above steps are repeated on and the pulse detection results of on-pulse signal S511 to S531 are corrected to “0.”

As for the method of correcting pulse detection results, methods that are easy to implement may be selected, and possible methods include, for example, providing a memory section for memorizing information about the non-use interval Tb for each detection result “1” inside pulse detection value correcting section 223, so that it is possible to memorize information about the non-use interval Tb for the time “1” is detected when a pulse detection result is “1,” check regularly whether or not the time “1” is detected coincides a non-use interval Tb memorized in the memory section and correct a pulse detection result if the time “1” is detected coincides with a non-use interval Tb memorized in the memory section, and memorizing all uncorrected pulse detection results in a memory section and correct them all together when all have been checked.

By this means, when “1” is detected in a non-use interval Tb provided in association with the main pulse of an on-pulse signal, it is decided that a delayed pulse is present and the pulse detection result is corrected to “0,” so that it is possible to extract from pulse detection results only the results for main pulses and reduce the influence of multipath propagation.

Furthermore, due to the influence of multipath propagation and such, cases may occur where “1” is detected at times there are not supposed to be the main pulse or delayed pulses of an on-pulse signal. Generally speaking, if the main pulse of an on-pulse signal is correctly detected as “1,” the pulse detection result in a non-use interval for the pulse detection result is also detected as “1,” due to delayed pulses. It follows that, if the pulse detection result in a non-use interval Tb is “0,” it is possible to decide that the source pulse detection result is wrong due to the influence of noise and such. Such cases may be coped with by, for example, adjusting the threshold value in the comparator used in pulse detecting section 221, retransmitting pulse radio transmission signals with greater power and providing known data patterns in intermediate positions so as to prevent chains of wrong detections and corrections from occurring.

Then, using the pulse detection results acquired thus, demodulating section 230 demodulates the transmission data. To be more specific, if three pulse detection results in a symbol interval Ts are all “0's,” “0” is obtained as demodulated data. On the other hand, if “1” is included in one of the three pulse detection results in a symbol interval Ts, “1” is obtained as demodulated data.

Incidentally, the concept of time slots shown in FIG. 14 is introduced again with pulse receiving apparatus 200 and processings such as pulse detection result correction are carried out in time slot units in a discrete manner, so that implementation is made more convenient.

As described above, according to the present embodiment, focusing upon the delay time of delayed pulses of an on-pulse signal arriving late after the main pulse due to the influence of multipath propagation and such, non-use intervals Ts are provided only in timings delayed pulses arrive and pulses are not transmitted in the non-use intervals Tb, so that it is possible to prevent, reliably, inter-pulse interference that is produced when the main pulses and delayed pulses of on-pulse signals or off-pulses signals arrive at the same time at the receiving end, and, as a result, prevent deterioration of received quality in the multipath propagation environment. Generally speaking, according to reports, an average value of delay spread with indoor channels is in the range between 20 nanoseconds and 30 nanoseconds at 5 to 30 meter antenna intervals. Therefore, if the symbol interval Ts is short such as several nanoseconds like in UWB and the average multipath propagation delay time D is substantially shorter than the symbol interval Ts, when non-use intervals Tb are provided only in timings the delayed pulses of an on-pulse signal arrive at the receiving end as in the present embodiment, as opposed to the case where non-use intervals in which pulses cannot be transmitted are provided only in part in time from between the time when the main pulse of an on-pulse signal arrives and the time the delay time passes, it is possible to reduce the proportion of time pulses cannot be transmitted, and, as a result, minimize the decrease of data throughput caused by inserting non-use intervals.

Furthermore, a symbol interval Ts is divided into several time slots and pulses are allocated to the time slots in a distributed manner, so that it is possible to whiten the spectrums. By contrast with this, if pulses repeat being transmitted in the same positions in the symbol intervals Ts, spectrum components derive from the carrier frequency, every symbol interval, due to the repetition cycle of pulse transmissions, and there are cases where these spectrum components have higher peak levels than the spectrum components of the pulses. Consequently, in a radio system where the upper limit value of transmission power is defined with the peak value, spectrum components that are produced due to the repetition cycle become limiting factors and requires reduction of transmission power, and there is therefore a problem securing transmission distance. Furthermore, a line spectrum having a high peak power, is more likely to cause damage against other systems.

Nevertheless, according to the present embodiment, one of a plurality of time slots in a symbol interval Ts is selected to avoid non-use intervals Tb and on-pulse signals are allocated in a distributed manner and transmitted, so that it is possible to reduce the peak level of spectrum components that are produced due to the repetition cycle, and whiten the spectrums. As a result of this, in a radio system where transmission power is limited at a peak value, like a UWB system, it is possible to improve the propagation distance and reduce interference against other systems.

### Embodiment 3

Primary configurations of the pulse transmitting apparatus and pulse receiving apparatus according to the present embodiment are the same as in embodiment 1 (i.e. see FIG. 3 and FIG. 5) and therefore their explanations will be omitted. The pulse transmitting apparatus according to the present embodiment is different from embodiment 1 in the method of providing non-use intervals Tb in non-use interval providing section 120 and in the method of pulse position adjustment in pulse position adjusting section 130.

Furthermore, assume that information about the delay time of the main pulse and delayed pulses arriving at pulse receiving apparatus 200 of the communicating party is reported in advance from pulse transmitting apparatus 100 to pulse receiving apparatus 200 as in embodiment 1. Furthermore, pulse transmitting apparatus 100 according to the present embodiment is different from embodiment 2 in that pulses are allocated over the entire proportion of a symbol interval Ts in time.

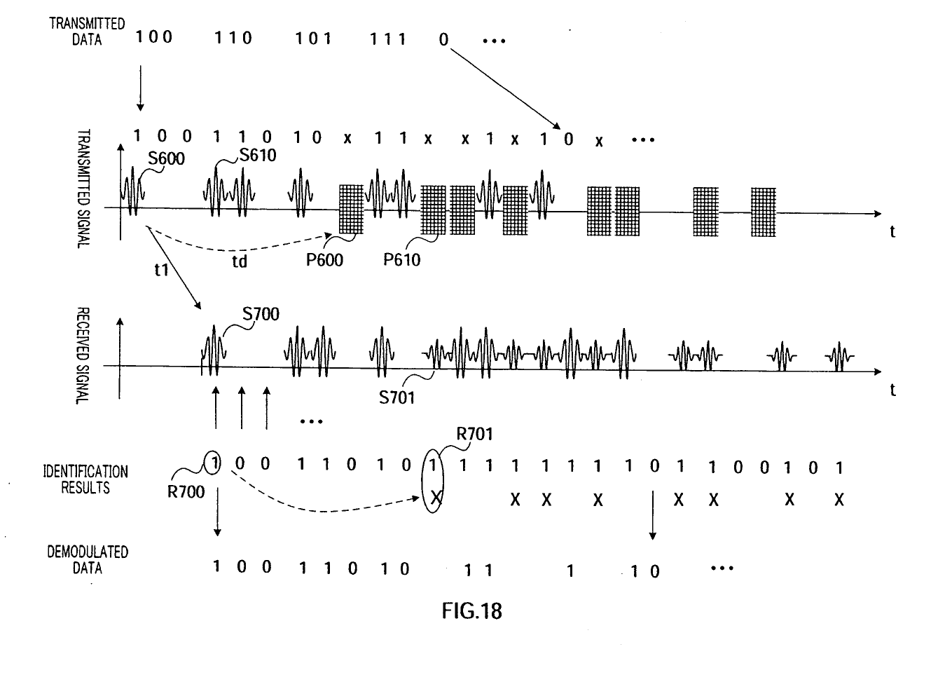

Next, the operations of pulse transmitting apparatus 100 and receiving apparatus 200 will be described in detail with reference to the accompanying drawings. FIG. 18 shows the relationships between transmission data, radio pulse modulated signal transmission timings, receiving timings of the main pulses and delayed pulses of on-pulse signals, pulse identification results and demodulated data. To begin with, in association with the first transmission data “1,” pulse modulating section 110 generates a pulse in which the pulse occupies an interval of a length that equals a symbol interval Ts.

Then, based on the starting position of an on-pulse signal, non-use interval providing section 120 provides a non-use interval Tb after a td of the on-pulse signal starting position. The td is a period of time that equals the delay time. In FIG. 18, P600 is the non-use interval Tb provided in association with on-pulse signal S600. The non-use interval Tb provided (P600) is memorized in non-use interval providing section 120. For transmission data “0,” pulse modulating section 110 does not generate an on-pulse signal, and non-use interval providing section 120 does not provide a non-use interval Tb.

Then, pulse position adjusting section 130 adjusts pulse positions such that pulses are not allocated in non-use intervals Tb. For example, a pulse is not allocated in the non-use interval Tb (P600) provided in association with on-pulse signal S600, but is shifted to a pulse position P600 later and transmitted.

The radio pulse modulated signal is demodulated as follows. First, with the radio pulse modulated signal, pulse detecting section 221 detects whether or not there is an on-pulse signal, and the pulse detection result is memorized in pulse detection value memorizing section 222.

Then, pulse detection value correcting section 223 corrects the pulse detection result. To be more specific, if a time where “1” is detected coincides with a non-use interval Tb provided in association with a time where “1” is detected earlier, the pulse detection result is corrected from “1” to “0.” For example, referring to FIG. 18, the time delayed pulse S701 of on-pulse signal S700 is received coincides with a non-use interval Tb (P610) provided in association with on-pulse signal S610, so that the pulse detection result “1” with delayed pulse S701 (R701) is corrected to be null. In FIG. 18, the “X” symbols are detection results that are nullified. Afterwards, the above steps are repeated and the pulse detection results are corrected.

Then, nullified pulse detection results are removed from the corrected pulse detection results, and the demodulated data is obtained.

As described above, according to the present embodiment, pulses are allocated using the entirety of a symbol interval Ts the pulse occupying interval, a non-use interval Tb is provided the delay time td after a symbol interval Ts, and all part in time where non-use intervals Tb are not provided is used as the part where pulses can be transmitted, so that it is possible to transmit more data per fixed time compared to the case of dividing a symbol interval Ts evenly into several and allocating pulses in a distributed manner by selecting between the time slots.

However, with the present embodiment, the amount of data that can be transmitted depends on the number of “1's” in the entire data, and therefore it is not possible to fix the data transmission rate. However, what data is going to be transmitted is known in advance, so that it is possible to estimate the amount of data that can be transmitted per unit time, that is, the transmission rate, by estimating the overall length of non-use interval Tb from the number of “1's” in the entire data.

Furthermore, although cases have been described above where OOK modulation is performed for pulse modulation, it is possible to derive the same above effect using ASK modulated signals as on-pulse signals.

One aspect of the transmitting apparatus of the present invention employs a configuration including: a pulse generating means that generates a pulse according to data to be transmitted; an acquiring means that acquires a delay time, which a delayed pulse takes behind a main pulse to arrive at a communicating party; a non-use interval providing means that provides a non-use interval, in which a pulse is not transmitted, based on the delay time; a pulse position adjusting means that adjusts a pulse position of the pulse such that the pulse is not transmitted in the non-use interval; and a radio transmitting means that transmits a pulse signal, the pulse signal comprising the pulse, which is converted to a radio frequency band in a pulse position adjusted by the pulse position adjusting means.

According to this configuration, when an on-pulse signal produces delayed pulses of non-zero power values due to multipath propagation, non-use intervals are provided such that subsequent pulses do not arrive at timings delayed pulses of the on-pulse signal arrive at the communicating party, so that it is possible to prevent delayed pulses of an on-pulse signal and subsequent pulses from arriving at the communicating party superimposing upon one another and reduce inter-pulse interference produced due to the influence of multipath propagation.

Another aspect of the transmitting apparatus of the present invention employs a configuration in which the non-use interval providing means provides a non-use interval immediately after a symbol interval in which an on-pulse signal is transmitted.

According to this configuration, after an on-pulse signal arrives at the communicating party, subsequent pulses do not arrive at the communicating party until the delayed pulses of the on-pulse signals arrive at the communicating party, so that it is possible to reliably prevent delayed pulses of an on-pulse signal and subsequent pulses from arriving at the communicating party superimposed upon one another and reduce reliably inter-pulse interference that is produced due to the influence of multipath propagation.

Another aspect of the transmitting apparatus of the present invention employs a configuration in which, if on-pulse signals are transmitted in consecutive symbol intervals, the non-use interval providing means provides the non-use interval between the symbol intervals.

According to this configuration, if on-pulse signals are not transmitted in consecutive symbol intervals, non-use intervals are not provided, so that it is possible to reduce inter-pulse interference produced due to the influence of multipath propagation and reduce the proportion of non-use intervals compared to the above second aspect, and reduce the decrease in throughput.

Another aspect of the transmitting apparatus of the present invention employs a configuration further having a differential flag generating means that generates a differential flag from a bit transition of transmission data to be allocated to the consecutive symbol intervals, and, in this configuration, the non-use interval providing means determines whether or not the on-pulse signals are transmitted in the consecutive symbol intervals using the differential flag.

According to this configuration, whether or not on-pulse signals are transmitted in consecutive symbols is transmitted is decided conveniently bit transitions of transmission data.

Another aspect of the pulse transmitting apparatus of present invention employs a configuration in which: the pulse generating means generates a pulse in which a pulse occupying interval equals a interval length defined by dividing a symbol interval evenly; and the non-use interval providing means provides a non-use interval that equals the interval length of the pulse occupying interval.

According to this configuration, if the delay time is longer than the symbol interval, a non-use interval that equals a pulse occupying interval is provided at the timing a delayed pulse of an on-pulse signal arrives at the communicating party as opposed to the main pulse of the on-pulse signal, so that, compared to the aspect in which a non-use interval that equals the delay time is provided immediately after a symbol interval where an on-pulse signal is transmitted, it is possible to minimize the proportion of non-use intervals, minimize the decrease of throughput and reduce inter-pulse interference that is produced from the influence of multipath propagation.

Another aspect of the pulse transmitting apparatus of the present invention employs a configuration in which, in one symbol interval, the pulse position adjusting means adjusts the pulse position on a per pulse occupying interval basis.

According to this configuration, it is possible to adjust pulse positions in units of the pulse occupying interval, and, given that pulse positions are adjusted in a symbol interval avoiding the non-use intervals in the same symbol interval, the positions where on-pulse signals are transmitted are distributed between symbol intervals, so that it is possible to prevent inter-pulse interference that is produced due to the influence of multipath propagation, and, compared to the case of transmitting on-pulse signals in fixed timings in symbol intervals, reduce the peak levels of spectrum components that occur due to the repetitions of symbol intervals.

Another aspect of the transmitting apparatus of the present invention employs a configuration in which: the pulse generating means generates a pulse in which a pulse occupying interval equals a symbol interval; the non-use interval providing means inserts, between symbol intervals, the non-use interval that equals the interval length of the pulse occupying interval; and the pulse position adjusting means adjusts the pulse position on a per symbol interval basis.

According to this configuration, pulse positions are shifted in symbol interval units to prevent pulses form being transmitted in non-use intervals, so that it is possible to prevent inter-pulse interference that is produced due to the influence of multipath propagation by simple pulse position control. Furthermore, a pulse occupying interval and a symbol interval are made equal and there is no proportion of a symbol interval where a pulse is not transmitted, so that, compared to the case where a pulse occupying interval is equal to a interval length determined by dividing evenly a symbol interval into several, it is possible to transmit more transmission data per fixed time.

One aspect of the pulse receiving apparatus of the present invention employs a configuration having: a pulse receiving means that receives a pulse signal transmitted from a communicating party; a pulse detecting means that detects whether or not there is a pulse, by sampling the pulse signal received in the receiving means, at time intervals of the pulse occupying interval in which the pulse signal is allocated; a correcting means that corrects a pulse detection result in a pulse occupying interval overlapping a delay time which a delayed pulse takes behind a main pulse to arrive at the pulse receiving apparatus, such that there is no pulse; and a demodulating means that generates demodulated data from the pulse detection result corrected by the correcting means.

According to this configuration, if a point in time where a pulse is detected to be present is a non-use interval, it is possible to correct the pulse detection result in the non-use interval such that a pulse does not exist, so that, even when a wrong detection is made in a non-use interval that there is a pulse due to the influence of noise, it is possible to remove this error and carry out correct demodulation.

One aspect of the pulse communication system of the present invention employs a configuration having: a pulse transmitting apparatus comprising: a pulse generating means that generates a pulse according to data to be transmitted; an acquiring means that acquires a delay time which a delayed pulse takes behind a main pulse to arrive at a communicating party; a non-use interval providing means that provides a non-use interval, in which a pulse is not transmitted, based on the delay time; a pulse position adjusting means that adjusts a pulse position of the pulse such that the pulse is not transmitted in the non-use interval; and a radio transmitting means that transmits a pulse signal, the pulse signal comprising the pulse, which is converted to a radio frequency band in a pulse position adjusted by the pulse position adjusting means; and a pulse receiving apparatus comprising: a receiving means that receives the pulse signal; a measuring means that measures a time a delayed pulse of an on-pulse signal takes to be received after a main pulse of the on-pulse signal is received, as the delay time; a pulse detecting means that detects whether or not there is a pulse in the received pulse signal by sampling the received pulse signal at time intervals of the pulse occupying interval in which the pulse signal is allocated; a correcting means that corrects, amongst pulse detection results produced in the pulse detecting means, a pulse detection result in a pulse occupying interval overlapping the delay time, such that there is no pulse; and a demodulating means that generates demodulated data from the pulse detection result corrected by the correcting means.

According to this configuration, when anon-pulse signal produces delayed pulses of non-zero power values due to multipath propagation, non-use intervals are provided such that subsequent pulses do not arrive at timings delayed pulses of the on-pulse signal arrive at the communicating party, so that it is possible to prevent delayed pulses of an on-pulse signal and subsequent pulses from arriving at the communicating party superimposing upon one another and reduce inter-pulse interference produced due to the influence of multipath propagation. Furthermore, at the receiving end, if a point in time where a pulse is detected to be present is a non-use interval, it is possible to correct the pulse detection result in the non-use interval such that a pulse does not exist, so that, even when a wrong detection is made in a non-use interval that there is a pulse due to the influence of noise, it is possible to remove this error and carry out correct demodulation.

One aspect of the pulse communication method of the present invention includes: generating a pulse according to data to be transmitted; acquiring a delay time which a delayed pulse takes behind a main pulse to arrive at a communicating party; providing a non-use interval in which a pulse is not transmitted, based on the delay time; adjusting a pulse position of the pulse such that the pulse is not transmitted in the non-use interval; and transmitting a pulse signal, the pulse signal comprising the pulse, which is converted to a radio frequency band in an adjusted pulse position.

According to this method, when an on-pulse signal produces delayed pulses of non-zero power values due to multipath propagation, non-use intervals are provided such that subsequent pulses do not arrive at timings delayed pulses of the on-pulse signal arrive at the communicating party, so that it is possible to prevent delayed pulses of an on-pulse signal and subsequent pulses from arriving at the communicating party superimposing upon one another and reduce inter-pulse interference produced due to the influence of multipath propagation.

The disclosure of Japanese Patent Application No. 2006-201359, filed on Jul. 24, 2006, including the specification, drawings and abstract, is incorporated herein by reference in its entirety.

### INDUSTRIAL APPLICABILITY

The pulse transmitting apparatus, pulse receiving apparatus, pulse communication system and pulse communication method of the present invention make it possible to prevent inter-pulse interference that is produced due to the influence of multipath propagation, and improve received quality, with a relatively simple method, and are therefore suitable for use in pulse transmitting apparatuses, pulse receiving apparatuses, pulse communication systems and pulse communication methods adopting high speed pulse communication such as UWB.

1. A pulse transmitting apparatus comprising:
a pulse generating section that generates a pulse according to data to be transmitted;
an acquiring section that acquires a delay time, which a delayed pulse takes behind a main pulse to arrive at a communicating party;
a non-use interval providing section that provides a non-use interval, in which a pulse is not transmitted, based on the delay time;
a pulse position adjusting section that adjusts a pulse position of the pulse such that the pulse is not transmitted in the non-use interval; and
a radio transmitting section that transmits a pulse signal, the pulse signal comprising the pulse, which is converted to a radio frequency band in a pulse position adjusted by the pulse position adjusting section.

2. The pulse transmitting apparatus according to claim 1, wherein the non-use interval providing section provides the non-use interval immediately after a symbol interval in which an on-pulse signal is transmitted.

3. The pulse transmitting apparatus according to claim 1, wherein, if on-pulse signals are transmitted in consecutive symbol intervals, the non-use interval providing section provides the non-use interval between the symbol intervals.

4. The pulse transmitting apparatus according to claim 3, further comprising a differential flag generating section that generates a differential flag from a bit transition of transmission data to be allocated to the consecutive symbol intervals,
wherein the non-use interval providing section determines whether or not the on-pulse signals are transmitted in the consecutive symbol intervals using the differential flag.

5. The pulse transmitting apparatus according to claim 1, wherein:
the pulse generating section generates a pulse in which a pulse occupying interval equals a interval length defined by dividing a symbol interval evenly; and
the non-use interval providing section provides a non-use interval that equals the interval length of the pulse occupying interval.

6. The pulse transmitting apparatus according to claim 5, wherein, in one symbol interval, the pulse position adjusting section adjusts the pulse position on a per pulse occupying interval basis.

7. The pulse transmitting apparatus according to claim 1, wherein:
the pulse generating section generates a pulse in which a pulse occupying interval equals a symbol interval;
the non-use interval providing section inserts, between symbol intervals, the non-use interval that equals the interval length of the pulse occupying interval; and
the pulse position adjusting section adjusts the pulse position on a per symbol interval basis.

8. A pulse receiving apparatus comprising:
a pulse receiving section that receives a pulse signal transmitted from a communicating party;
a pulse detecting section that detects whether or not there is a pulse, by sampling the pulse signal received in the receiving section, at time intervals of the pulse occupying interval in which the pulse signal is allocated;
a correcting section that corrects a pulse detection result in a pulse occupying interval overlapping a delay time which a delayed pulse takes behind a main pulse to arrive at the pulse receiving apparatus, such that there is no pulse; and
a demodulating section that generates demodulated data from the pulse detection result corrected by the correcting section.

9. A pulse communication system comprising:
a pulse transmitting apparatus comprising:
a pulse generating section that generates a pulse according to data to be transmitted;
an acquiring section that acquires a delay time which a delayed pulse takes behind a main pulse to arrive at a communicating party;
a non-use interval providing section that provides a non-use interval, in which a pulse is not transmitted, based on the delay time;
a pulse position adjusting section that adjusts a pulse position of the pulse such that the pulse is not transmitted in the non-use interval; and
a radio transmitting section that transmits a pulse signal, the pulse signal comprising the pulse, which is converted to a radio frequency band in a pulse position adjusted by the pulse position adjusting section; and
a pulse receiving apparatus comprising:
a receiving section that receives the pulse signal;
a measuring section that measures a time a delayed pulse of an on-pulse signal takes to be received after a main pulse of the on-pulse signal is received, as the delay time;
a pulse detecting section that detects whether or not there is a pulse in the received pulse signal by sampling the received pulse signal at time intervals of the pulse occupying interval in which the pulse signal is allocated;
a correcting section that corrects, amongst pulse detection results produced in the pulse detecting section, a pulse detection result in a pulse occupying interval overlapping the delay time, such that there is no pulse; and
a demodulating section that generates demodulated data from the pulse detection result corrected by the correcting section.

10. A pulse communication method comprising the steps of:
generating a pulse according to data to be transmitted;
acquiring a delay time which a delayed pulse takes behind a main pulse to arrive at a communicating party;
providing a non-use interval in which a pulse is not transmitted, based on the delay time;
adjusting a pulse position of the pulse such that the pulse is not transmitted in the non-use interval; and
transmitting a pulse signal, the pulse signal comprising the pulse, which is converted to a radio frequency band in an adjusted pulse position.
